(19) United States
(12) Patent Application Publication
(10) Pub. No.: US 2012/0255594 A1
(43) Pub. Date: Oct. 11, 2012

(54) Solar Power Generator Module

(75) Inventors: Peeush Kumar Bishnoi, Bangalore (IN); Ganapathi Subbu Sethuvenkatraman, Maduarai (IN)

(73) Assignee: SIEMENS AKTIENGESELLSCHAFT, München (DE)

(21) Appl. No.: 13/516,772

(22) PCT Filed: Dec. 18, 2009
(86) PCT No.: PCT/EP2009/009147

§ 371 Date: Jun. 18, 2012

(51) Int. Cl. H01L 31/052

(52) U.S. Cl. 136/246

(57) ABSTRACT

A solar power generator module includes a first type of photovoltaic cell and a second type of photovoltaic cell. The second type of photovoltaic cell is different from the first type of photovoltaic cell. The module further includes an optical device adapted to concentrate light onto the first type of photovoltaic cell and to transmit diffused light to the second type of photovoltaic cell.

### CROSS REFERENCE TO RELATED APPLICATIONS

This application is the US National Stage of International Application No. PCT/EP2009/009147, filed Dec. 18, 2009 and claims the benefit thereof. All of the applications are incorporated by reference herein in their entirety.

### FIELD OF INVENTION

The present invention relates to a solar power generator module for a solar power generator system.

### BACKGROUND OF INVENTION

Renewable energy solutions have gained significance in recent timings due to depleting natural resources of fossil fuels. Generating electrical power using sun's radiation is the most environment friendly renewable energy solution. Electrical power may be generated directly using sun's radiation into electricity using photovoltaic (PV) systems. Typically, the electrical power produced is proportional to the sunlight incident on the surface of the PV systems.

Concentrated photovoltaic (CPV) systems have been developed for increasing the electrical power produced per unit area of a cell. CPV systems typically employ concentrator systems to concentrate sun's radiation onto a CPV cell. Only direct sunlight or direct normal isolation (DNI) can be concentrated efficiently and diffused sunlight may not be efficiently concentrated or sometimes not concentrated at all. Diffused sunlight is the sunlight scattered by the atmosphere, clouds, etc., and additionally the light reflected by the ground and other objects. Therefore, a CPV system operates efficiently to produce electrical power during sunny conditions rather than cloudy conditions or under cloud cover. Thus, CPV systems are preferred in areas having high DNI.

### SUMMARY OF INVENTION

It is an object of the embodiments of the invention to produce electrical power in a solar power generator module using concentration of light and still producing electrical power from diffused light.

The above object is achieved by the features of the independent claim(s).

The first type of photovoltaic cell produces electrical power on concentrated light being incident onto the photovoltaic surface. The second type of photovoltaic cell produces electrical power on the incident of diffused light on the photovoltaic surface. The optical means is adapted to concentrate light onto the first type of photovoltaic cell and to transmit diffused light to the second type of photovoltaic cell. Thus, the second type of photovoltaic cell produces electrical power using diffused light. This enables the module to produce electrical power using both concentrated light and diffused light.

According to another embodiment, the light concentrated is direct sunlight. Direct sunlight may easily be concentrated onto the first type of photovoltaic cell by the optical means.

According to yet another embodiment, the first type of photovoltaic cell is a concentrated photovoltaic cell. The concentrated photovoltaic cell provides increased electrical power produced per unit area of a cell. This results in increased efficiency of the module. The concentrated photovoltaic cell requires relatively less amount of active photovoltaic material, and thus, reduction in cost also is achieved.

According to yet another embodiment, the module may further comprise a base for supporting the first type of photovoltaic cell. The first type of photovoltaic cell is arranged at the base such that light may be concentrated onto the first type of photovoltaic cell.

According to yet another embodiment, the second type of photovoltaic cell is arranged between the optical means and a base. For example, the second type of photovoltaic cell may be arranged in the space between the base and the optical means of the module. This eliminates requirement of additional space for arranging the second type of photovoltaic cell.

According to yet another embodiment, the second type of photovoltaic cell is arranged on an area of a base, the area being unoccupied by the first type of photovoltaic cell. Typically, the surface area of the base is larger than the area of the first type of photovoltaic cell as the surface area of the base may be near about or equal to the surface area of the optical means. To achieve effective concentration ratio, the surface area of the optical means is typically larger than the area of the first type of photovoltaic cell. Concentration ratio is defined as an area occupied by the optical means to an area occupied by the first type of photovoltaic cell. As the first type of photovoltaic cell occupies only a portion of an area of the base, the second type of photovoltaic cell may be arranged in an area of the base unoccupied by the first type of photovoltaic cell.

According to yet another embodiment, a plurality of the first type of photovoltaic cells are arranged in a spaced pattern and the second type of photovoltaic cell is arranged in the spaces between the first type of photovoltaic cells.

According to yet another embodiment, the second type of photovoltaic cell is arranged on a path of the light incident on the first type of photovoltaic cell, the second type of photovoltaic cell being transparent to allow light to pass through. The second type of photovoltaic cell being transparent enables is arranging the second type of photovoltaic cell on the path of the incident light. As the second type of photovoltaic cell is transparent, the light shall pass through the cell.

According to yet another embodiment, the second type of photovoltaic cell is arranged at a first side of the optical means, the first side being proximate to the first type of photovoltaic cell, a photovoltaic surface of the second type of photovoltaic cell being distal to the optical means. The second type of photovoltaic cell may be arranged at the first side of the optical means as the second type of photovoltaic cell produces electrical power on incident of diffused light on the photovoltaic surface. The diffused light incident on the photovoltaic surface of the second type of photovoltaic cell is the diffused light passing through the optical means. The second type of photovoltaic cell may posses a property of transparency so that the concentrated light and diffused light is allowed to pass though.

According to yet another embodiment, the second type of photovoltaic cell is arranged at a second side of the optical means, the second side being distal to the first type of photovoltaic cell, a photovoltaic surface of the second type of photovoltaic cell being proximate to the optical means. For example, the second type of photovoltaic cell in the present embodiment may be removably arranged at the second side of the optical means.

According to yet another embodiment, the module may further comprise a reflector for reflecting diffused light onto the second type of photovoltaic cell, the reflector being arranged between the optical means and the base. The reflector reflects the diffused light onto the second type of photovoltaic cell. The reflector may be positioned in between the base and the optical means as the base and optical means are spaced apart. In an aspect, the reflector may be a coating of a reflective material. In an aspect, the reflector may also be arranged at the base at an area unoccupied by the first type of photovoltaic cell.

According to yet another embodiment, the second type of photovoltaic cell is arranged at a second side of the optical means, the second side being distal to the first type of photovoltaic cell, a photovoltaic surface of the second type of photovoltaic cell being distal to the optical means. For example, the second type of photovoltaic cell in the present embodiment may be removably arranged at the second side of the optical means.

According to yet another embodiment, the second type of photovoltaic cell is arranged at a first side of the optical means, the first side being proximate to the first type of photovoltaic cell, a photovoltaic surface of the second type of photovoltaic cell being proximate to the optical means. The diffused light transmitted by the optical means is received by the photovoltaic surface of the second type of photovoltaic cell. The concentrated light passes through the second type of photovoltaic cell to be incident onto the first type of photovoltaic cell.

According to yet another embodiment, the second type of the photovoltaic cell is a non-concentrated photovoltaic cell. The second type of photovoltaic cell being a non-concentrated photovoltaic cell enables the second type of photovoltaic cell to produce electrical power on receiving diffused light.

According to yet another embodiment, the second type of photovoltaic cell is a thin-film photovoltaic cell.

According to yet another embodiment, the optical means is a refractive lens with an optical axis, the lens being arranged such that the optical axis passes through the first type of photovoltaic cell. The optical axis passing though the first type of photovoltaic cell enables efficient concentrated on light onto the first type of photovoltaic cell.

Another embodiment includes a solar power generator array comprising the solar power generator module.

Another embodiment includes a solar power generator system, comprising the solar power generator array.

### BRIEF DESCRIPTION OF THE DRAWINGS

Embodiments of the present invention are further described hereinafter with reference to illustrated embodiments shown in the accompanying drawings, in which:

FIG. 1 illustrates a plan view of a solar power generator module according to an embodiment herein,

FIG. 2 illustrates a side view of the solar power generator module 1 of FIG. 1 according to a first embodiment,

FIG. 3 in an example shows the electrical power produced by the second type of photovoltaic cells as a function of a concentration ratio,

FIG. 4 illustrates a side view of the solar power generator module 1 of FIG. 1 according to a second embodiment,

FIG. 5 illustrates a solar power generator array comprising a plurality of solar power generator modules of FIG. 1 according to an embodiment herein,

FIG. 6 illustrates a solar power generator system according to an embodiment herein, and

FIG. 7 with reference to FIG. 1 and FIG. 6 illustrates a current produced by the plurality of arrays of the solar power generator system of FIG. 6 as a function of time.

### DETAILED DESCRIPTION OF INVENTION

Various embodiments are described with reference to the drawings, wherein like reference numerals are used to refer to like elements throughout. In the following description, for purpose of explanation, numerous specific details are set forth in order to provide a thorough understanding of one or more embodiments. It may be evident that such embodiments may be practiced without these specific details.

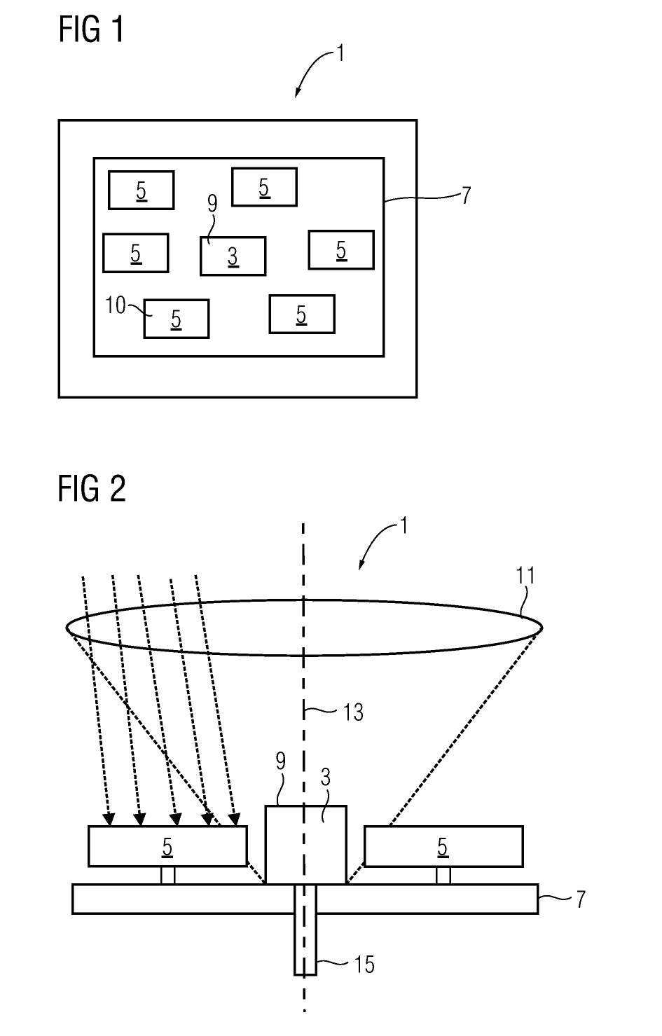

Referring to FIG. 1, a plan view of a solar power generator module 1 is illustrated according to an embodiment herein. In the shown example of FIG. 1, the module 1 comprises a first type of a photovoltaic cell 3 and second type of photovoltaic cells 5 arranged at a base 7. In the present embodiment, the base 7 supports the first type of photovoltaic cell 3 and the second type of photovoltaic cells 5. The first type of photovoltaic cell 3 and the second type of photovoltaic cells 5 are different from one another. For example, the first type of photovoltaic cell 3 may operate efficiently to produce electrical power upon incident of concentrated light on a photovoltaic surface 9 of the first type of photovoltaic cell 3. The second type of photovoltaic cells 5 may produce electrical power upon incident of diffused light on a photovoltaic surface 10 of the second type of photovoltaic cells 5.

According to an embodiment, the first type of photovoltaic cell 3 may be a concentrated photovoltaic cell (CPV) as direct sunlight may be efficiently concentrated onto the photovoltaic surface 9 of the first type of photovoltaic cell 3. The second type of photovoltaic cell 5 may be a non-concentrated photovoltaic cell (PV) as the PV may operate on receiving direct or diffused sunlight. In an aspect, the first type of photovoltaic cell 3 and the second type of photovoltaic cell 5 may be a single-junction photovoltaic cell or a multi-junction photovoltaic cell.

Still referring to FIG. 1, the module 1 comprises an optical means adapted to concentrate sunlight onto the first type of photovoltaic cell 3 and to transmit diffused sunlight to the second type of photovoltaic cells 5. To achieve an effective concentration ratio, an area of the optical means is required to be very large compared to an area of the first type of photovoltaic cell 3. The concentration ratio is a ratio of an area occupied by the optical means to an area occupied by the first type of photovoltaic cell 3. Thus, the module 1 may be designed such that it may accommodate optical means having large area to achieve effective concentration ratio. Thus, as the area of the optical means is very large compared to the area of the first type of photovoltaic cell 3, the base 7 may accommodate a plurality of second type of photovoltaic cells 5. In an aspect, the module 1 comprising the first type of photovoltaic cell 3, the second type of photovoltaic cell 5, the base 7 and the optical means may be environmentally-sealed to protect the cells 3, 5 from dust and moisture.

FIG. 2 illustrates a side view of the solar power generator module 1 according to a first embodiment herein. In the shown example of FIG. 2, the optical means 11 concentrates sunlight onto the first type of photovoltaic cell 3 and provides diffused light to the second type of photovoltaic cells 5. In the present embodiment the optical means 11 illustrated is a refractive device, such as a fresnel lens, a prismatic lens and the like.

Advantageously, the optical means is arranged such that sunlight may be concentrated efficiently onto the photovoltaic surface 9 of the first type of photovoltaic cell 3. For example, the optical means 11 may be arranged such that an optical axis 13 passes through the first type of photovoltaic cell 3 arranged at the base 7. Typically, the optical axis 13 for a lens is an imaginary line passing through the center of curvature of each surface of the lens. Advantageously, the optical means 11 may be arranged such that the first type of photovoltaic cell 3 is within a distance of the focal length of the optical means 11 and the optical axis passes through the cell 3. Arranging the optical means 11 such that the first type of photovoltaic cell 3 is within the distance of the focal length of the lens and the optical axis passes through the cell 3 enables the optical means 11 to concentrate sunlight onto the photovoltaic surface 9 of the cell 3 efficiently. In an aspect, the first type of photovoltaic cell 3 may comprise a heat sink 15 for dissipating heat.

Referring still to FIG. 2, the first type of photovoltaic cell 3 typically occupies an area on the base 7 that is a fraction of a surface area of the optical means 11. Typically, the surface area of the optical means 11 is very large compared to the area of the first type photovoltaic cell 3. The surface area of the optical means 11 is large because direct sunlight is to be concentrated on the first type photovoltaic cell 3. The larger the surface area of the optical means 11 the higher is the concentration ratio. Thus to achieve effective concentration of sunlight onto the first type photovoltaic cell 3, the surface area of the optical means 11 is typically larger than the area of the first type photovoltaic cell 3.

Thus, the surface area of the base 7 is very large compared to the area of the first type photovoltaic cell 3 as the surface area of the base 7 may be approximately equal to the surface area of the optical means 11. However in certain embodiments, the surface area of the base 7 may be larger or less than the surface area of the optical means 11 depending on the construction of an enclosure housing the module 1 and on the heat dissipation technique used.

Referring still to FIG. 2, in an embodiment, the second type of photovoltaic cells 5 may be arranged between the optical means 11 and the base 7. As the optical means 11 and the base 7 are spaced apart for efficient concentration of sunlight onto the first type of photovoltaic cell 3, the second type of photovoltaic cell 5 may be arranged in a space between the base 7 and the optical means 11.

Referring still to FIG. 2, the second type of photovoltaic cells 5 may be arranged at the base 7 at an area unoccupied by the first type of photovoltaic cell 3. As the second type of photovoltaic cells 5 are arranged at the base 7 without requirement of any additional space, the size of the module 1 is the same. The second type of photovoltaic cells 5 may receive diffused sunlight passing though the optical means 11. In the shown example, two second type of photovoltaic cells 5 have been illustrated only as an example. A single second type of photovoltaic cell 5 or more than two cells 5 may be arranged at the base 7 as desired. In an embodiment, a plurality of first type of photovoltaic cells 3 may be arranged at the base 7 in a spaced pattern and second type of photovoltaic cells 5 may be arranged in the space between the first type of cells 3. The optical means 11 may be adapted such that sunlight may be concentrated onto each of the first type of cells 3. In another embodiment, the second type of photovoltaic cell 5 may be arranged at a height above the base 7. Arranging the second type of photovoltaic cell 5 at a height above the base 7 provides a gap. The gap may enable in dissipating heat from the second type of photovoltaic cell 5 as a heat dissipating device may be positioned in the gap.

Thus, the first type of photovoltaic cell 3 produces electrical power upon receiving the concentrated sunlight and the second type of photovoltaic cell 5 produces electrical power upon incident of diffused sunlight. This facilitates the solar power generator module 1 to produce electrical power in direct sunlight condition and diffuse sunlight condition. Thus, the electrical power produced by the module 1 is stable irrespective of the lighting condition. Moreover, as the first type of photovoltaic cell 3 is a CPV cell, the efficiency of electrical power produced is increased as the CPV cell produces relatively higher electrical power per unit area of the cell.

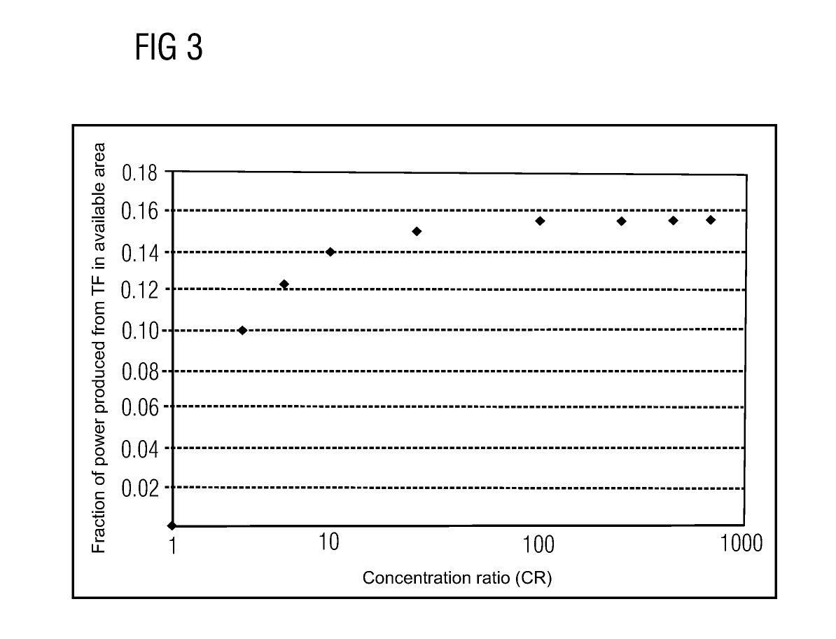

FIG. 3 in an example shows the electrical power produced by the second type of photovoltaic cells as a function of a concentration ratio. In the shown example of FIG. 3, it is assumed that the second type of photovoltaic cells 5 of FIG. 2 are thin-film photovoltaic cells. The second type of photovoltaic cells 5 produce 15% of the output produced by the first type of photovoltaic cells 3 at a concentration ratio of 50. Optimum benefits as illustrated in the present example may be obtained by maintaining a concentration ratio of 50 or greater than 50.

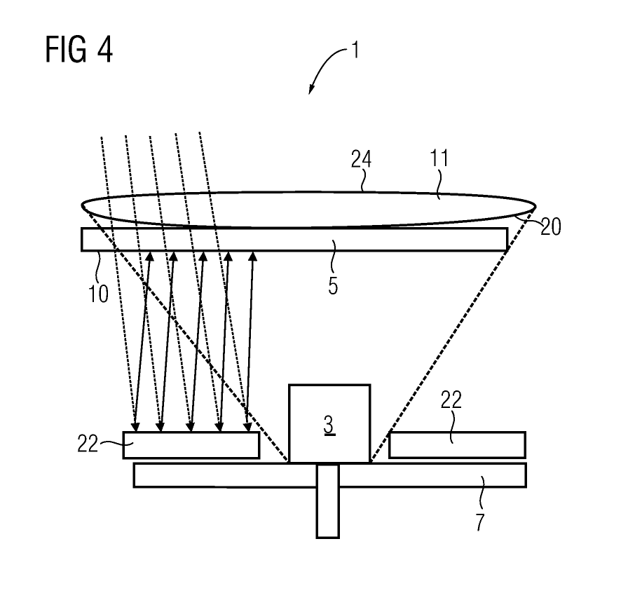

FIG. 4 illustrates a side view of the solar power generator module 1 according to an embodiment herein. In an embodiment, the second type of photovoltaic cell 5 may be arranged on a path of the light incident on the first type of photovoltaic cell 3. The second type of photovoltaic cell 5 in the present embodiment may be transparent to allow light to pass through. In the shown example of FIG. 4, the second type photovoltaic cell 5 is arranged at a first side 20 of the optical means 11, the photovoltaic surface 10 of the second type of photovoltaic cell 5 being distal to the optical means 11. The first side 20 of the optical means 20 is proximate to the first type of cell 3. Reflectors 22 may be arranged on the base 7 on the area unoccupied by the first type of photovoltaic cell 3 to reflect the diffuse sunlight received through the optical means 11 and through the second type of photovoltaic cell 5 onto the photovoltaic surface 10 of the second type photovoltaic cell 5. The reflectors 22 may be a mirror, a reflective coating and the like. As the transparent photovoltaic cell typically posses a property of transparency, the transparent photovoltaic cell permits the concentrated sunlight and the diffused sunlight to pass through with little attenuation. The concentrated light is provided to the first type of photovoltaic cell 3 and the diffused sunlight is provided to the second type of photovoltaic cell 5 via the reflectors 22. In an aspect the second type of photovoltaic cell 5 is a thin-film photovoltaic cell. The thin-film photovoltaic cell being flexible provides the advantage of arranging the thin-film photovoltaic cell onto the optical means 11 having uneven surfaces also.

Still referring to FIG. 4, in an alternate embodiment, the second type of photovoltaic cell 5 may be arranged at the first side 20 of the optical means 11, the photovoltaic surface 10 of the second type of photovoltaic cell 5 being proximate to the optical means 11. The second type of photovoltaic cell 5 in the present embodiment receives the diffused sunlight transmitted by the optical means and allows the concentrated sunlight to pass through. The concentrated light passing through the second type of photovoltaic cell 5 may be received by the first type of photovoltaic cell. The second type of photovoltaic cell 5, in the present embodiment, receives the diffused sunlight directly and thus reflectors are not required to reflect the diffused sunlight onto the second type of photovoltaic cell 5.

Referring still to FIG. 4, in another embodiment, the second type of photovoltaic cell 5 may be arranged at a second side 24 of the optical means 11, the photovoltaic surface 10 of the second type of photovoltaic cell 5 being proximate to the optical means 11. The second side 24 of the optical means is distal to the first type of photovoltaic cell 3. The reflectors 22 arranged on the base 7 reflect the diffused light received to the photovoltaic surface 10 of the second type of photovoltaic cell 5. In yet another embodiment, the second type of photovoltaic cell 5 may be arranged at the second side 24 of the optical means 11, the photovoltaic surface 10 of the second type of photovoltaic cell 5 being distal to the optical means 11. In the present embodiment, the second type of photovoltaic cell 5 may receive the diffused sunlight directly and thus reflectors are not required to reflect the diffused sunlight onto the second type of photovoltaic cell 5.

Additionally, the second type of photovoltaic cell 5 may be removably arranged at the second side 24 of the optical means 11 and thus may be removed when not required. For, example the second type of photovoltaic cell may be removed if it is anticipated that the weather at a particular geographical location shall be clear with significant direct sunlight for a significant duration.

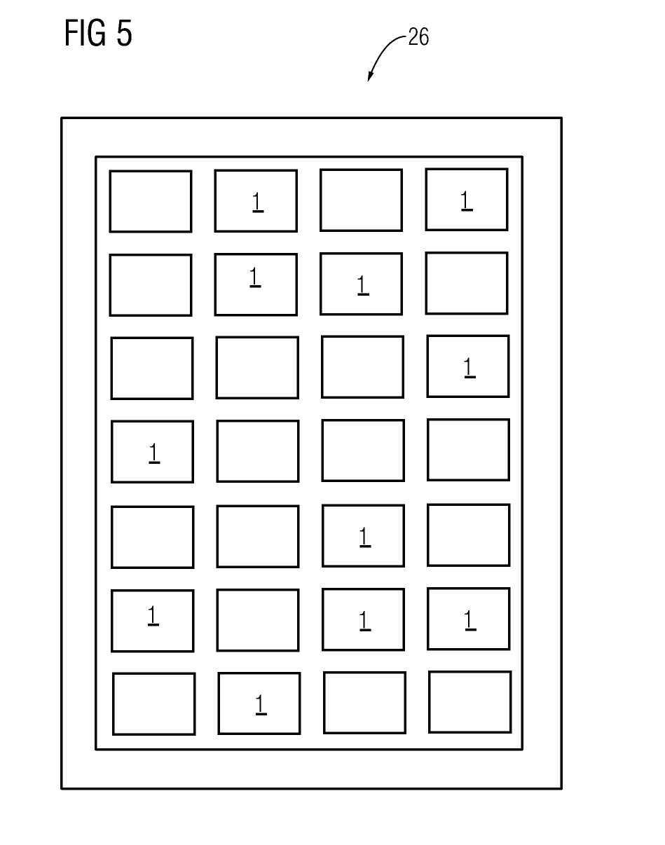

FIG. 5 illustrates a solar power generator array 26 comprising a plurality of solar power generator modules 1 of FIG. 1 according to an embodiment. The solar power generator array 26 comprises a plurality of modules 1 comprising the first type of photovoltaic cell 3 of FIG. 1 and the second type of photovoltaic cells 5 of FIG. 1. The first type of photovoltaic cell 3 produces electrical power during direct sunlight condition and the second type of photovoltaic cell 5 produces electrical power during diffuse sunlight condition. Thus, a single array 26 may produce electrical power during both sunny conditions and cloudy conditions.

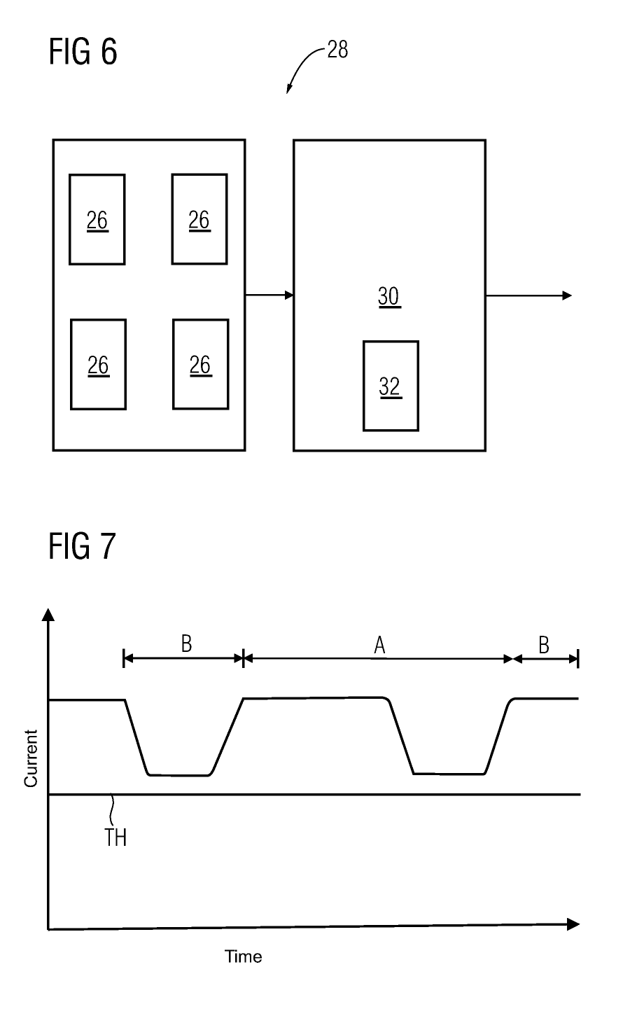

FIG. 6 illustrates a solar power generator system 28 according to an embodiment herein. In the shown example of FIG. 5, the solar power generator system 28 comprises a plurality of solar power generator arrays 26 and a balance of system equipment (BOS) 30. The BOS 30 includes the necessary wiring systems for protection, conditioning and dc to ac conversion. Typically, the electrical power produced by the array 26 is dc power. To convert the dc power produced by the array 26 to ac power, the BOS may comprise an inverter 32. As the array 26 produces electrical power during sunlight condition and cloudy condition, the electrical power provided to the inverter 32 is stable. The electrical power is stable as the electrical power produced is continuously above a threshold required for optimum operation of the inverter. In the shown example of FIG. 6, the solar power generator system 28 is illustrated comprising a plurality of arrays 26. However, in some embodiments, the solar power generator system 28 may comprise a single array 26.

FIG. 7 with reference to FIG. 1 and FIG. 6 illustrates a current produced by the plurality of arrays 26 in the solar power generator system 28 as a function of time. In shown example of FIG. 7, it shown that the current produced by the arrays 26 is maintained above a threshold TH. Time period A illustrates the current produced during sunny conditions and the time period B illustrates the current produced during cloud cover. The first type of photovoltaic cell 3 produces the current during A as the first type of photovoltaic cell 3 produces electrical power on incident of concentrated sunlight on the photovoltaic surface 9. The second type of photovoltaic cell 5 produces the current during B as the second type of photovoltaic cell 3 produces electrical power on incident of diffused sunlight on the photovoltaic surface 10. The generation of current during both A and B enable the current to be maintained above the threshold TH. This avoids tripping of the inverter 32 and thus, enables efficient operation of the inverter 32.

The embodiments described herein enable in producing electrical power in solar power generator systems using concentration of sunlight and still producing electrical power from diffused sunlight. Moreover, the electrical power produced is stable as the electrical power is produced during both sunny conditions and cloudy conditions. Additionally, this enables in operating the solar power generator array with to produce increased electrical output per unit area. Moreover, tripping of the inverter is avoided as the electrical power provided to the inverter is stable. Additionally, as the second type of photovoltaic cells 5 are arranged in the modules 1 without increasing the size of the modules 1, requirement of additional space is eliminated. Thus, a single array 26 may produce electrical power during both sunny conditions and cloudy conditions.

While this invention has been described in detail with reference to certain preferred embodiments, it should be appreciated that the present invention is not limited to those precise embodiments. Rather, in view of the present disclosure which describes the current best mode for practicing the invention, many modifications and variations would present themselves, to those of skill in the art without departing from the scope and spirit of this invention. The scope of the invention is, therefore, indicated by the following claims rather than by the foregoing description. All changes, modifications, and variations coming within the meaning and range of equivalency of the claims are to be considered within their scope.

1-18. (canceled)

19. A solar power generator module, comprising:
a first type of photovoltaic cell,
a second type of photovoltaic cell different from the first type of photovoltaic cell, and
an optical device that concentrates light onto the first type of photovoltaic cell and transmits diffused light to the second type of photovoltaic cell.

20. The solar power generator module according to claim 19, wherein the light concentrated is direct sunlight.

21. The solar power generator module according to claim 19, wherein the first type of photovoltaic cell is a concentrated photovoltaic cell.

22. The solar power generator module according to claim 19, further comprising a base for supporting the first type of photovoltaic cell.

23. The solar power generator module according to claim 22, wherein the second type of photovoltaic cell is arranged between the optical device and the base.

24. The solar power generator module according to claim 19, wherein the second type of photovoltaic cell is arranged on an area of the base, the area being unoccupied by the first type of photovoltaic cell.

25. The solar power generator module according to claim 24, wherein a plurality of the first type of photovoltaic cells are arranged in a spaced pattern and the second type of photovoltaic cell is arranged in the spaces between the first type of photovoltaic cells.

26. The solar power generator module according to claim 19, wherein the second type of photovoltaic cell is arranged on a path of the light incident on the first type of photovoltaic cell, the second type of photovoltaic cell being transparent to allow light to pass through.

27. The solar power generator module according to claim 26, wherein the second type of photovoltaic cell is arranged at a first side of the optical device, the first side being proximate to the first type of photovoltaic cell, a photovoltaic surface of the second type of photovoltaic cell being distal to the optical device.

28. The solar power generator module according to claim 26, wherein the second type of photovoltaic cell is arranged at a second side of the optical device, the second side being distal to the first type of photovoltaic cell, a photovoltaic surface of the second type of photovoltaic cell being proximate to the optical device.

29. The solar power generator module according to claim 27, further comprising a reflector for reflecting diffused light onto the second type of photovoltaic cell, the reflector being arranged between the optical device and the base.

30. The solar power generator module according to claim 26, wherein the second type of photovoltaic cell is arranged at a second side of the optical device, the second side being distal to the first type of photovoltaic cell, a photovoltaic surface of the second type of photovoltaic cell being distal to the optical device.

31. The solar power generator module according to claim 26, wherein the second type of photovoltaic cell is arranged at a first side of the optical device, the first side being proximate to the first type of photovoltaic cell, a photovoltaic surface of the second type of photovoltaic cell being proximate to the optical device.

32. The solar power generator module according to claim 19, wherein the second type of the photovoltaic cell is a non-concentrated photovoltaic cell.

33. The solar power generator module according to claim 19, wherein the second type of photovoltaic cell is a thin-film photovoltaic cell.

34. The solar power generator module according to claim 19, wherein the optical device is a refractive lens with an optical axis, the lens being arranged such that the optical axis passes through the first type of photovoltaic cell.

35. A solar power generator array, comprising the solar power generator module according to claim 19.

36. A solar power generator system solar power generator module, comprising the solar power generator array according to claim 35.
